(19) United States
(12) Patent Application Publication
(10) Pub. No.: US 2026/0169241 A1
(43) Pub. Date: Jun. 18, 2026

(54) OPTICAL MODULE WITH LIQUID COOLING

(71) Applicant: II-VI Delaware, Inc., Wilmington, DE (US)

(72) Inventors: Ting Shi, Wilmington, DE (US); Tao Chen, Wilmington, DE (US); Xiaobiao Zhu, Wilmington, DE (US); Jun Dang, Wilmington, DE (US); Yanbing Gong, Wilmington, DE (US); Yu Tao, Wilmington, DE (US); Lina Yi, Wilmington, DE (US)

(21) Appl. No.: 18/978,744

(22) Filed: Dec. 12, 2024

(51) Int. Cl. G02B 6/42; H05K 7/20

(52) U.S. Cl. CPC G02B 6/4268; H05K 7/20272; H05K 7/20281

(57) ABSTRACT

This disclosure describes systems and methods for liquid cooling an optical module. A liquid is input to a first port of the optical module. The liquid flows through a channel of the optical module until it is output from a second port of the optical module. Heat generated by the optical module is transferred to the liquid, thereby raising the temperature of the liquid. The flow of the liquid may be controlled by a pump that is operably coupled to a cooler. The cooler may comprise a radiator and fan that reduce the temperature of the liquid before it is reinput to the optical module. Liquid cooling requires less power than other methods than other method for optical module cooling. Cooling the optical module reduces bit error rate though the optical transceiver pathway.

### CROSS REFERENCE TO RELATED APPLICATIONS

N/A

### BACKGROUND

Limitations and disadvantages of traditional methods and systems for cooling an optical module will become apparent to one of skill in the art, through comparison of such approaches with some aspects of the present method and system set forth in the remainder of this disclosure with reference to the drawings.

### BRIEF SUMMARY

Systems and methods for liquid cooling an optical module, substantially as illustrated by and/or described in connection with at least one of the figures, are set forth more completely in the claims.

### BRIEF DESCRIPTION OF THE DRAWINGS

FIGS. 1A-B illustrate a first example optical module with liquid cooling, in accordance with various example implementations of this disclosure.

FIGS. 2A-B illustrate a second example optical module with liquid cooling, in accordance with various example implementations of this disclosure.

FIGS. 3A-B illustrate a third example optical module with liquid cooling, in accordance with various example implementations of this disclosure.

FIG. 4 illustrates an example data center using an example optical module with liquid cooling, in accordance with various example implementations of this disclosure.

FIG. 5 illustrates a first example system using an optical module with liquid cooling, in accordance with various example implementations of this disclosure.

FIG. 6 illustrates a second example system using an optical module with liquid cooling, in accordance with various example implementations of this disclosure.

### DETAILED DESCRIPTION

This disclosure relates to cooling systems for optical transceiver modules. The disclosed system may comprise an Octal Small Form Factor Pluggable (OSFP) optical module that uses liquid cooling.

Liquid cooling requires less power than other methods for optical module cooling. Cooling the optical module reduces the bit error rate though the optical transceiver pathway.

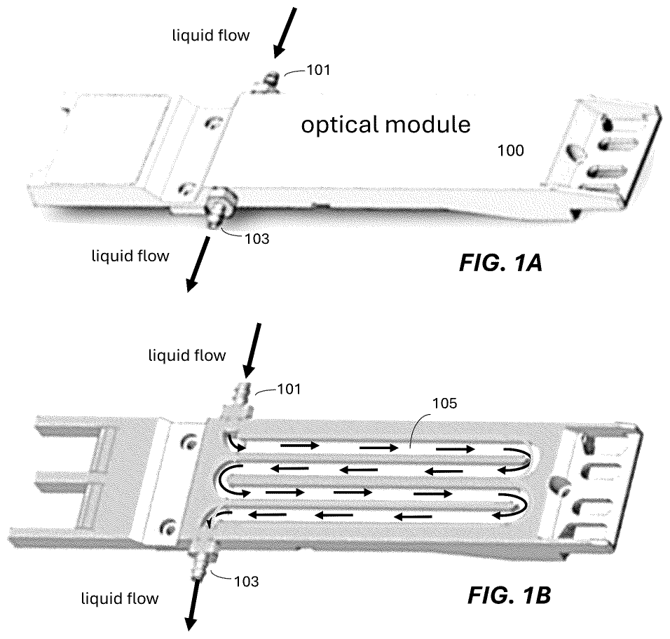

FIG. 1A illustrates an external view of a first example optical module with liquid cooling, in accordance with various example implementations of this disclosure. FIG. 1B illustrates an internal view of the first example optical module with liquid cooling, in accordance with various example implementations of this disclosure.

A liquid is input to a first port 101 of the optical module 100. The liquid flows through a channel 105 of the optical module 100 until it is output from a second port 103 of the optical module 100. As illustrated, the first port 101 and the second port 103 are configured horizontally with respect to the optical module 100. Such an arrangement may be beneficial for use in a data center or networking system where access to the sides of the optical module 100 is available.

To allow heat conductivity, the channel 105 may comprise metal or other material with similar thermal conductivity, such as reaction-bonded silicon carbide. For example, channel 105 may comprise stainless steel with a conductivity of 15-25 W/(m K), aluminum alloy with a conductivity of 121-151 W/(m K), and/or copper with a conductivity of 400 W/(m K). The channel 105 may be manufactured by 3D printing or friction stir welding. As illustrated, the channel may be manufactured as a pathway through a material.

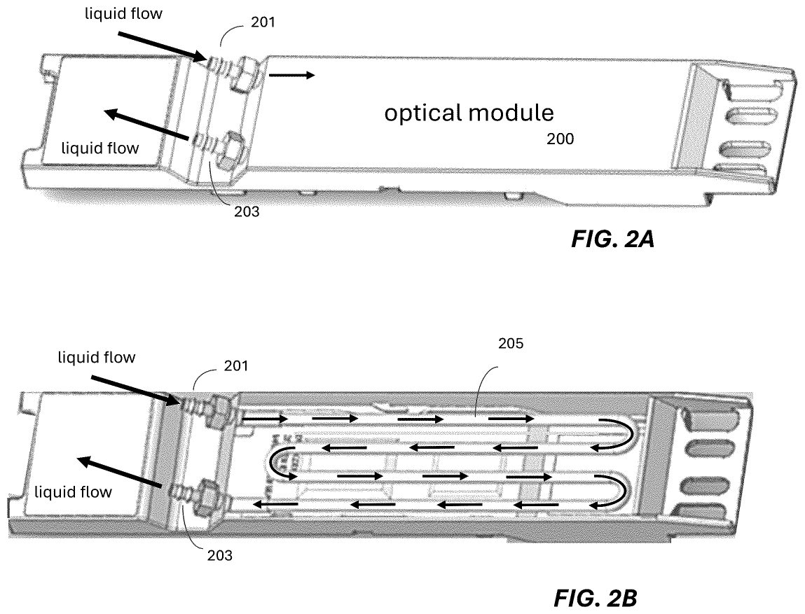

FIG. 2A illustrates an external view of a second example optical module with liquid cooling, in accordance with various example implementations of this disclosure. FIG. 2B illustrates an internal view of the second example optical module with liquid cooling, in accordance with various example implementations of this disclosure.

A liquid is input to a first port 201 of the optical module 200. The liquid flows through a channel 205 of the optical module 200 until it is output from a second port 203 of the optical module 200. As illustrated, the first port 201 and the second port 203 are configured vertically with respect to the optical module 200. Such an arrangement may be beneficial for use in a data center or networking system where access to the top of the optical module 200 is available.

To allow heat conductivity, the channel 205 may comprise metal or other material with similar thermal conductivity, such as reaction-bonded silicon carbide. For example, channel 205 may comprise stainless steel with a conductivity of 15-25 W/(m K), aluminum alloy with a conductivity of 121-151 W/(m K), and/or copper with a conductivity of 400 W/(m K). The channel 205 may be manufactured by 3D printing or friction stir welding. As illustrated, the channel may be manufactured as a pipeline of material.

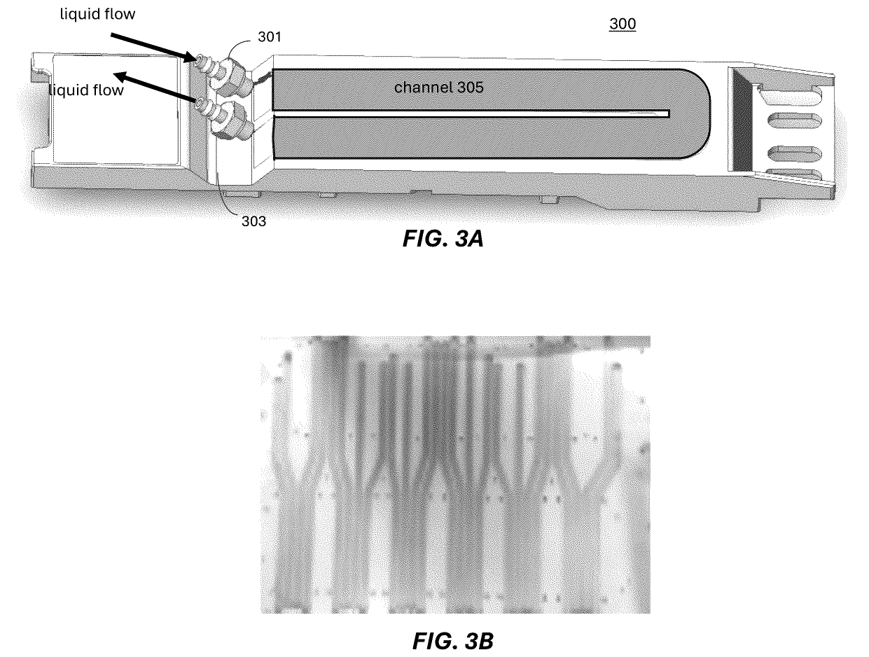

FIG. 3A illustrates an internal view of a third example optical module with liquid cooling, in accordance with various example implementations of this disclosure. FIG. 3B illustrates layers of the third example optical module with liquid cooling, in accordance with various example implementations of this disclosure.

A liquid is input to a first port 301 of the optical module 300. The liquid flows through a channel 305 of the optical module 300 until it is output from a second port 303 of the optical module 300. As illustrated, the first port 301 and the second port 303 are configured vertically with respect to the optical module 300. Such an arrangement may be beneficial for use in a data center or networking system where access to the top of the optical module 300 is available, although in other embodiments the ports 301 and 305 may be configured horizontally as in FIGS. 1A and 1B.

To allow heat conductivity, the channel 305 may comprise metal or other material with similar thermal conductivity, such as reaction-bonded silicon carbide. For example, channel 305 may comprise stainless steel with a conductivity of 15-25 W/(m K), aluminum alloy with a conductivity of 121-151 W/(m K) and/or copper with a conductivity of 400 W/(m K). The channel 105 may be manufactured by 3D printing or friction stir welding. As illustrated, the channel may be manufactured as a pipeline embedded in the shell of the optical module 300.

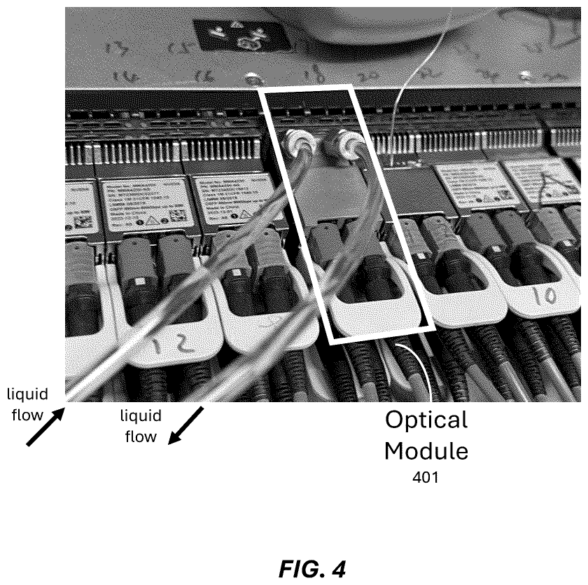

FIG. 4 illustrates an example data center using an example optical module 401 with liquid cooling, in accordance with various example implementations of this disclosure. As illustrated, access to the top of the optical module 401 is available.

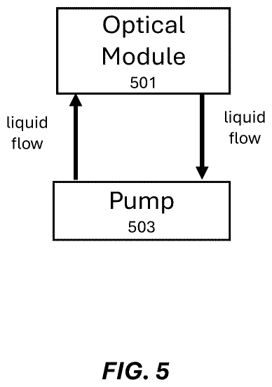

FIG. 5 illustrates a first example system using an optical module 501 with liquid cooling, in accordance with various example implementations of this disclosure.

Heat from the optical module 501 may be carried away by the circulation of liquid. The liquid may comprise, for example, deionized water or a coolant such as LC-25, which is available from the Dow Chemical Company.

Heat generated by the optical module 501 may be transferred to the liquid, thereby raising the temperature of the liquid. The flow of the liquid may be controlled by a pump 503 that is coupled to the optical module 501 via tubes. The diameter of these tubes may be greater than one half of the thickness of the shell of the optical module 501.

Liquid absorbs heat from the baseplate. As the liquid moves through the system the exposure to air helps it cool. Fans may also be attached to move the heat away from the system.

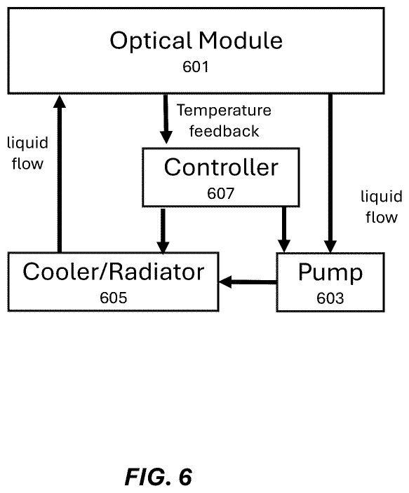

FIG. 6 illustrates a second example system using an optical module 601 with liquid cooling, in accordance with various example implementations of this disclosure.

The flow of the liquid may be controlled by a pump 603 that is operably coupled to a cooler/radiator 605. The cooler/radiator 605 may comprise a radiator and fan that reduce the temperature of the liquid before it is reinput to the optical module.

The temperature of the optical module 601 may be determined by several methods. For example, the temperature may be determined according to the change in wavelength of the optical signals communicated via the optical module 601. The temperature may allow the pump 603 adjust a flow rate. The temperature may also allow the cooler/radiator 605 to adjust a temperature of fluid before it reenters the optical module 601. A controller 607 may control the flow rate setting and/or the temperature setting.

While the present method and/or system has been described with reference to certain implementations, it will be understood by those skilled in the art that various changes may be made and equivalents may be substituted without departing from the scope of the present method and/or system. In addition, many modifications may be made to adapt a particular situation or material to the teachings of the present disclosure without departing from its scope. Therefore, it is intended that the present method and/or system not be limited to the particular implementations disclosed, but that the present method and/or system will include all implementations falling within the scope of the appended claims.

What is claimed is:

1. A system, wherein the system comprises:
an optical module comprising two ports and a channel, wherein the optical module is configured to allow a liquid to be input to the first port, flow through the channel and be output from the second port.

2. The system of claim 1, wherein the optical module is an Octal Small Form Factor Pluggable (OSFP) module.

3. The system of claim 1, wherein the first port and the second port are configured horizontally with respect to the optical module.

4. The system of claim 1, wherein the first port and the second port are configured vertically with respect to the optical module.

5. The system of claim 1, wherein the system comprises a data center.

6. The system of claim 1, wherein the system comprises a networking system.

7. The system of claim 1, wherein the channel comprises metal.

8. The system of claim 1, wherein the channel comprises one or more of stainless steel, aluminum alloy, and copper.

9. The system of claim 1, wherein the channel is manufactured by one or more of 3D printing and friction stir welding.

10. The system of claim 1, wherein the channel is configured as a pathway through a material.

11. The system of claim 1, wherein the channel is configured as a pipeline of material.

12. The system of claim 1, wherein the channel is embedded in a shell of the optical module.

13. The system of claim 1, wherein the liquid is at least one of deionized water and a coolant.

14. The system of claim 1, wherein a temperature of the optical module is determined according to a change in wavelength of an optical signals communicated via the optical module.

15. The system of claim 1, wherein the system comprises a pump coupled to the optical module via a plurality of tubes.

16. The system of claim 15, wherein a flow rate of the pump is dynamically adjustable according to a temperature of the optical module.

17. The system of claim 15, wherein the diameter of each tube is greater than one half of a thickness of a shell of the optical module.

18. The system of claim 1, wherein the system comprises a radiator operable to reduce a temperature of the liquid before it is input to the optical module.

19. The system of claim 18, wherein the radiator comprises a fan.

20. The system of claim 18, wherein the temperature of the liquid is dynamically adjustable according to a temperature of the optical module.
